(19) United States
(12) Patent Application Publication
(10) Pub. No.: US 2016/0180967 A1
(43) Pub. Date: Jun. 23, 2016

(54) SEMICONDUCTOR DEVICE

(71) Applicant: SK hynix Inc., Icheon-si Gyeonggi-do (KR)

(72) Inventor: Yong Soon PARK, Seoul (KR)

(21) Appl. No.: 14/710,166

(22) Filed: May 12, 2015

(30) Foreign Application Priority Data
Dec. 19, 2014 (KR) 10-2014-0184828

(51) Int. Cl. G11C 29/38; G11C 29/14

(52) U.S. Cl. CPC G11C 29/38; G11C 29/14

(57) ABSTRACT

A semiconductor device is provided. The semiconductor device may include first to third memory blocks including memory cells, and an operation circuit configured to perform an operation of the first to third memory blocks. The operation circuit may be configured to receive an algorithm from outside the semiconductor device and store the algorithm in the second memory block, and perform an operation of the first memory block based on the stored algorithm.

### CROSS-REFERENCE TO RELATED APPLICATION

The present application claims priority to Korean patent application number 10-2014-0184828 filed on Dec. 19, 2014, in the Korean Intellectual Property Office, the entire disclosure of which is incorporated by reference herein.

### BACKGROUND

1. Technical Field

Various embodiments generally relate to a semiconductor device. More particularly, the various embodiments relate to a semiconductor device including a memory block.

2. Related Art

An operation circuit included in a semiconductor device may store data in a memory block based on a predetermined algorithm. The operation circuit included in the semiconductor device may read the data stored in the memory block based on a predetermined algorithm. However, the algorithm used is required to change as the number of performed operations increases or a process or design is changed, and operation characteristics decrease. The process of changing the algorithm is difficult.

### BRIEF SUMMARY

In an embodiment, a semiconductor device may include first to third memory blocks including memory cells, and an operation circuit configured to perform an operation of the first to third memory blocks. The operation circuit may be configured to receive an algorithm from outside the semiconductor device and store the algorithm in the second memory block, and perform an operation of the first memory block based on the stored algorithm.

In an embodiment, a semiconductor device may include memory blocks including memory cells. The semiconductor device may include an operation circuit including a ROM configured to store a first algorithm and a latch circuit configured to latch a second algorithm input from outside the semiconductor device, and may be configured to perform an operation of the memory blocks based on the first algorithm and the second algorithm.

### BRIEF DESCRIPTION OF THE DRAWINGS

FIG. 1 is a block diagram illustrating a representation of an example of a semiconductor device according to an embodiment.

FIG. 2 is a circuit diagram illustrating a representation of an example of a memory block according to an embodiment.

FIGS. 3A to 3C are views illustrating a representation of an example of a memory block according to an embodiment.

FIG. 4 is a flow chart illustrating a representation of an example of a method of operating a semiconductor device according to the various embodiments.

FIG. 5 is a view illustrating a representation of an example of a method of operating a semiconductor device according to an embodiment.

FIG. 6 is a block diagram illustrating a representation of an example of a structure of an electronic device according to an embodiment.

FIG. 7 is a view illustrating a representation of an example of a structure of a semiconductor device including a memory according to an embodiment.

### DETAILED DESCRIPTION

In the figures, the thicknesses of layers and regions are expressed for convenience of the explanation, and may be exaggerated with respect to an actual physical thickness. In the explanation of the various embodiments, a well known structure, may or may not be omitted. Various examples of the embodiments are described herein.

Various embodiments may be directed towards a semiconductor device capable of improving operation characteristics.

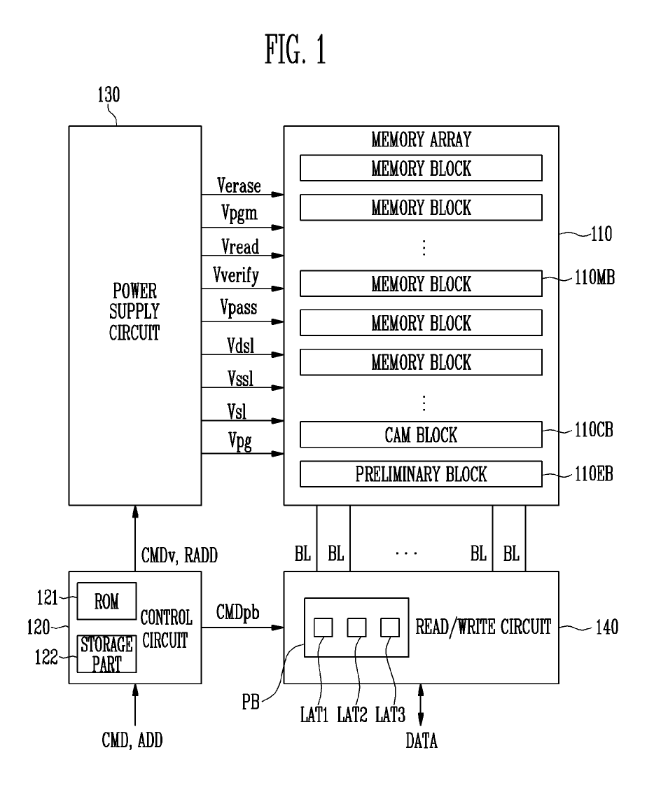

FIG. 1 is a block diagram illustrating a representation of an example of a semiconductor device according to an embodiment.

Referring to FIG. 1, the semiconductor device may include a memory array 110 and operation circuits 120 to 140. The memory array 110 may include a plurality of memory blocks 110MB, 110CB, and 110EB. Each of the memory blocks 110MB, 110CB, and 110EB may include a plurality of memory strings. Each of the memory strings may include a plurality of memory cells.

First memory blocks (or main memory blocks) 110MB among the memory blocks may be used to store data input from the outside or outside the semiconductor device. A second memory block (or a preliminary block) 110EB may be used to store an algorithm input from the outside or outside the semiconductor device. A third memory block (or a cam block) 110CB may be used to store data to set an operation condition (for example, a condition of a program operation or a condition of a read operation) of the operation circuits 120 to 140. The main memory 110MB, the preliminary block 110EB, and the cam block 110CM may be formed with the same structure or substantially the same structure.

In a flash memory device, the memory block may include a flash memory cell. The memory cell may include a floating gate formed of polysilicon and a charge storage layer formed of a nitride layer.

The memory strings may be connected to bit lines, respectively, and connected to a common source line in parallel. The memory strings may be formed on a semiconductor substrate in a 2-dimensional structure or a 3-dimensional structure. A structure of the memory block will be described below.

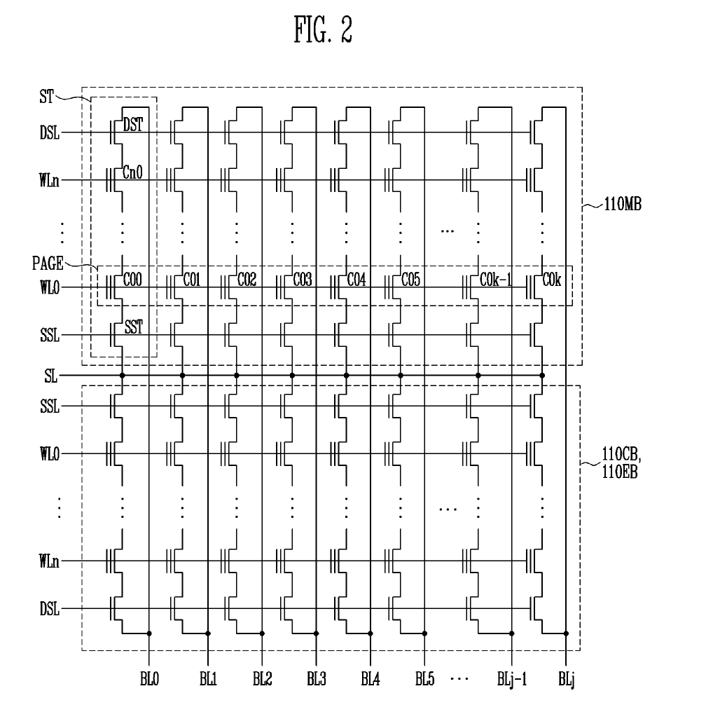

FIG. 2 is a view illustrating a representation of an example of a memory array according to an embodiment.

Referring to FIG. 2, each of the memory blocks 110MB, 110CB, and 110EB includes a plurality of memory strings ST connected between bit lines BL0 to BLj and a common source line SL. The memory strings ST are connected to corresponding bit lines BL0 to BLj, respectively, and commonly connected to the common source line SL. Each of the memory strings ST includes a source select transistor SST having a source connected to the common source line SL, a cell string including a plurality of memory cells C00 to Cn0 connected in series, and a drain select transistor DST having a drain connected to a bit line BL0. Memory cells C00 to Cn0 included in the cell string are connected in series between the select transistors SST and DST. A gate of the source select transistor SST is connected to a source select line SSL. Gates of the memory cells C00 to Cn0 are connected to word lines WL0 to WLn, respectively. A gate of the drain select transistor DST is connected to a drain select line DSL.

The drain select transistor DST controls a connection or a disconnection between the cell string and the bit line. The the source select transistor SST controls a connection or a disconnection between the cell string and the common source line SL.

In a NAND flash memory device, memory cells included in a memory block are classified into physical page units or logical page units. For example, memory cells C00 to C0k connected to one word line (for example, WL0) configure one physical page PAGE. Even numbered memory cells C00, C02, C04, and C0k-1 connected to one word line (for example, WL0) may configure an even page. Odd numbered memory cells C01, C03, C05, and C0k may configure an odd page. The above page (or, the even page and the odd page) may serve as a basic unit of a program operation or a read operation.

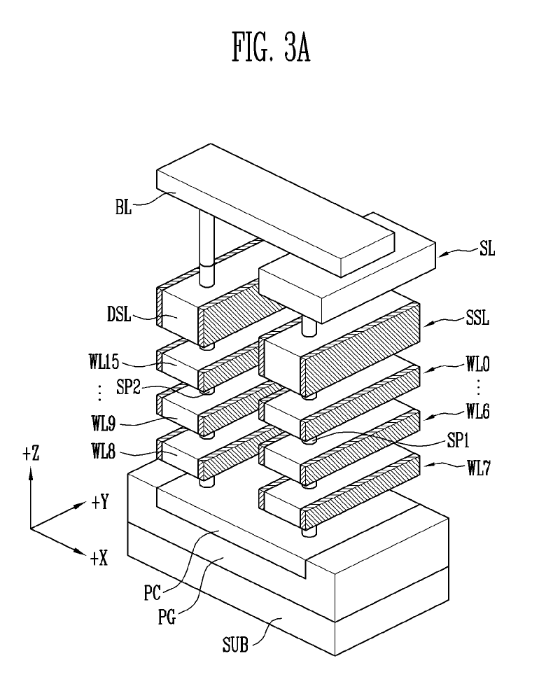

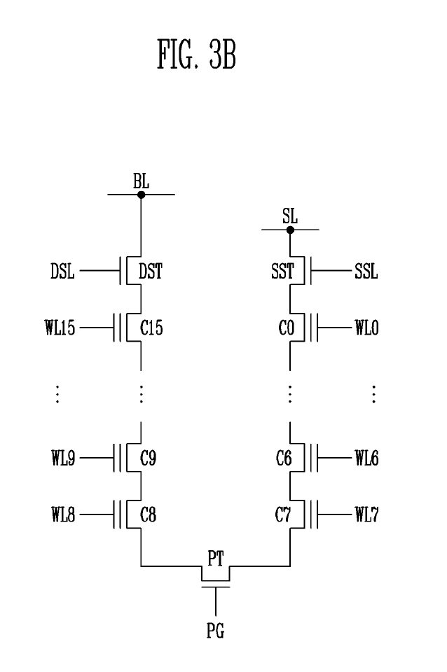

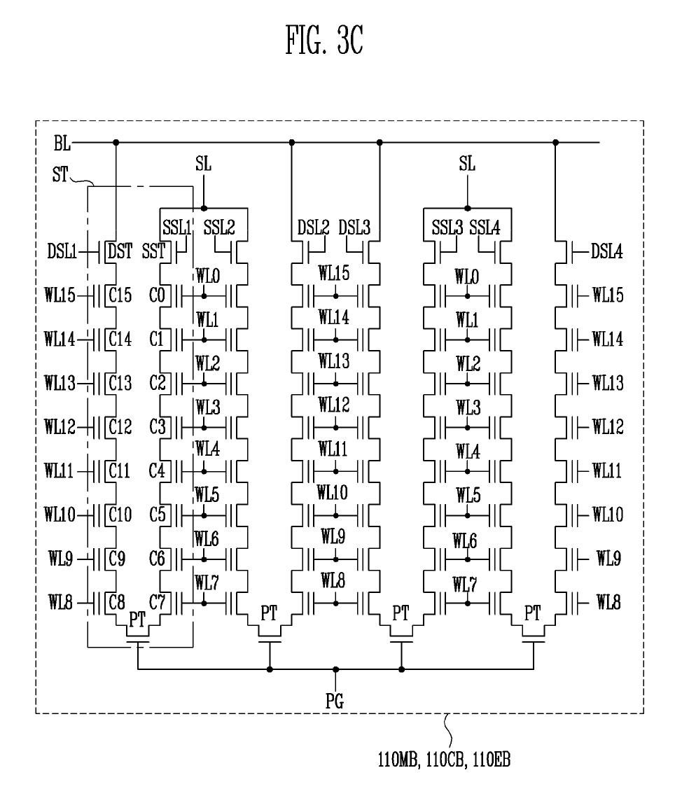

FIGS. 3A to 3C are views illustrating a representation of an example of a memory block according to an embodiment.

Referring to FIGS. 3A and 3B, a pipe gate PG including a recessed portion is formed on a semiconductor substrate SUB. A pipe channel layer PC is formed in the recessed portion of the pipe gate PG. A plurality of vertical channel layers SP1 and SP2 are formed on the pipe channel layer PC. An upper portion of a first vertical channel layer SP1 among the pair of the vertical channel layers is connected to a common source line SL. An upper portion of a second vertical channel layer SP2 is connected to a bit line BL. The vertical channel layers SP1 and SP2 may be formed of, for example but not limited to, polysilicon.

A plurality of first conductive layers DSL and WL15 to WL8 are formed at different heights of the second vertical channel layer SP2, and surround the second vertical channel layer SP2. A plurality of second conductive layers SSL and WL0 to WL7 are formed at different heights of the first vertical channel layer SP1, and surround the first vertical channel layer SP1. A multilayer (not illustrated) including a charge storage layer may be formed on surfaces of the vertical channel layers SP1 and SP2 and a surface of the pipe channel layer PC. The multilayer may be interposed between the vertical channel layers SP1 and SP2 and conductive layers DSL, WL15 to WL8, SSL, and WL0 to WL7 and between the pipe channel layer PC and the pipe gate PG.

An uppermost conductive layer surrounding the second vertical channel layer SP2 may be the drain select line DSL. The conductive layers under the drain select line DSL may be word lines WL15 to WL8. An uppermost conductive layer surrounding the first vertical channel layer SP1 may be the source select line SSL. Conductive layers under the source select line SSL may be the word lines WL0 to WL7. Some of the conductive layers used for the word lines may be dummy word lines (not illustrated).

The first conductive layers SSL and WL0 to WL7 and the second conductive layers DSL and WL15 to WL8 are each stacked in different areas of the semiconductor substrate. The first vertical channel layer SP1 passing through the first conductive layers SSL and WL0 to WL7 may be vertically connected between the source line SL and the pipe channel layer PC. The second vertical channel layer SP2 passing through the second conductive layers DSL and WL15 to WL8 may be vertically connected between the bit line BL and the pipe channel layer PC.

A drain select transistor DST is formed at a portion where the drain select line DSL surrounds the second vertical channel layer SP2. The main cell transistors C15 to C8 are formed at portions where the word lines WL15 to WL8 surround the second vertical channel layer SP2, respectively. A source select transistor SST is formed at a portion where the source select line SSL surrounds the first vertical channel layer SP1. The main cell transistors C0 to C7 are formed at portions where the word lines WL0 to WL7 surround the first vertical channel layer SP1.

According to the above embodiments, the memory string may include the drain select transistor DST and the main cell transistors C15 to C8 perpendicularly connected or substantially perpendicularly connected to the substrate SUB, between the bit line BL and the pipe channel layer PC. According to the above embodiments, the memory string may include the source select transistor SST and the main cell transistors C0 to C7 perpendicularly connected or substantially perpendicularly connected to the substrate SUB between the common source line CSL and the pipe channel layer PC. In the above embodiments, a dummy cell transistor (not illustrated) may further be connected between the select transistor DST or SST and the main cell transistor C15 or C0, and a dummy cell transistor (not illustrated) may further be connected between the main cell transistor C8 or C7 and a pipe transistor PT.

The source select transistor SST and the main cell transistors C0 to C7 connected between the common source line SL and the pipe transistor PT may configure a first vertical memory string. The drain select transistor DST and the main cell transistors C15 to C8 connected between the bit line BL and the pipe transistor PT may configure a second vertical memory string.

Referring to FIG. 3C, the memory block 110MB, for example, includes a plurality of memory strings ST connected to the bit lines BL. The memory string ST having a U-shape includes a first vertical memory string SST and C0 to C7 vertically connected between the common source line SL and the pipe transistor PT of the substrate. The memory string ST having a U-shape includes a second vertical memory string C8 to C15 and DST vertically connected between the bit line BL and the pipe transistor PT of the substrate. The first vertical memory string SST and C0 to C7 includes a source select transistor SST and memory cells C0 to C7. The source select transistor SST of the memory strings are controlled by voltages applied to source select lines SSL1 to SSL4, respectively. The memory cells C0 to C7 are controlled by voltages applied to stacked word lines WL0 to WL7, respectively. The second vertical memory string C8 to C15, and DST includes a drain select transistor DST and memory cells C8 to C15. The drain select transistor DST of the memory strings are controlled by voltages applied to drain select lines DSL1 to DSL4, respectively. The memory cells C8 to C15 are controlled by voltages applied to stacked word lines WL8 to WL15, respectively.

When a memory block 110MB is selected, the pipe transistor PT connected to a pair of memory cells C7 and C8 disposed at a center or substantially a center of the memory string having the U-shape performs an operation of connecting channel layers of the first vertical memory string SST and C0 to C7 included in a selected memory block 110MB to channel layers of the second vertical memory string C8 to C15 and DST.

In a memory block of a 2-dimensional structure, one memory string is connected to each bit line and drain select transistors of a memory block are controlled by one drain select line. In the memory block 110MB of the 3-dimensional structure, a plurality of the memory strings ST are commonly connected to each bit line BL. In the same memory block 110MB, the number of the memory strings ST commonly connected to one bit line BL and controlled by the same word lines may be changed according to a design.

Since the plurality of memory strings are connected to the one bit line BL in parallel, in order to selectively connect the one bit line BL to the memory strings ST, drain select transistors DST are independently controlled by select voltages applied to drain select lines DSL1 to DSL4.

In the memory block 110MB, the memory cells C0 to C7 of the first vertical memory string SST and C0 to C7 are vertically connected. The memory cells C8 to C15 of the second vertical memory string C8 to C15 and DST are vertically connected. The memory cells C0 to C7 of the first vertical memory string SST and C0 to C7 and the memory cells C8 to C15 of the second vertical memory string C8 to C15 and DST are controlled, respectively, by operating voltages applied to the stacked word lines WL0 to WL7 and the stacked word lines WL8 to WL15. The above word lines WL0 to WL15 may be classified into memory block units.

The select lines DSL1 to DSL4, SSL1, and SSL2 and the word lines WL0 to WL15 are local lines of the memory block 110MB. The source select lines SSL1 and SSL2 and the word lines WL0 to WL7 may serve as local lines of the first vertical memory string. The drain select lines DSL1 to DSL4 and the word lines WL8 to WL15 may serve as local lines of the second vertical memory string. The source select lines SSL3 and SSL4 and the word lines WL0 to WL7 may serve as local lines of the first vertical memory string. In the memory block 110MB, pipe gates PG of pipe transistors PT may be commonly connected.

In the memory block 110MB, memory cells connected to different bit lines and sharing a drain select line (for example, DSL4) may constitute one page PAGE. The memory block 110MB may serve as a basic unit of an erase loop, and the page PAGE may serve as a basic unit of a program operation and a read operation.

As illustrated in FIG. 2, the cam block 110CB and the preliminary block 110EB may be formed with the same structure or substantially the same structure as the memory block 110MB.

Referring again to FIGS. 1 and 3B, the operation circuits 120 to 140 may be configured to perform a program loop, an erase loop, and a read operation on memory cells C0 connected to selected word line (for example, WL0). The program loop may include a program operation and a verification operation, and the erase loop may include an erase operation and a verification operation. The operation circuits 120 to 140 may additionally perform a program operation (or a post program operation) for adjusting an erase level in which threshold voltages of memory cells are distributed after the erase loop.

In order to perform the program loop, the erase loop, and the read operation, the operation circuits 120 to 140 may be configured to selectively output operating voltages. The operating voltages may include, for example but are not limited to, Verase, Vpgm, Vread, Vverify, Vpass, Vdsl, Vssl, Vsl, and Vpg and may be applied to the local lines SSL, WL0 to WLn, PG, and DSL and the common source line SL of the selected memory block. The operating voltages may be used to control precharge/discharge of the bit lines BL or sense current flow (or voltage variation) of the bit lines BL.

In a NAND flash memory device, the operation circuits may include a control circuit 120, a voltage supply circuit (i.e., power supply circuit) 130, and a read/write circuit 140. Each of the above structures will be described below.

The power supply circuit 130 generates operating voltages Verase, Vpgm, Vread, Vverify, Vpass, Vdsl, Vssl, Vsl, and Vpg to perform the program loop, the erase loop, and the read operation at desired levels in response to a command signal CMD. The command signal may be input from outside the semiconductor device and to the control circuit 120. The control circuit 120 may control the voltage supply circuit 130. The operating voltages Verase, Vpgm, Vread, Vverify, Vpass, Vdsl, Vssl, Vsl, and Vpg may be applied to local lines SSL, WL0 to WL15, PG, and DSL of the selected memory block and the common source line SL. For example, the control circuit 120 may output a voltage control signal CMDv and a row address signal RADD to the voltage supply circuit 130. An address signal ADD may be input from outside the semiconductor device. In order to perform the program loop, the erase loop, and the read operation, the control circuit 120 controls precharge/discharge of the bit lines BL based on data to be stored in memory cells, or controls the read/write circuit 140 to sense current flow (or voltage variation) of the bit lines BL during the read operation or the verification operation. For example, the control circuit 120 may output an operation control signal CMDpb to the read/write circuit 140.

The voltage supply circuit 130 generates required operating voltages Verase, Vpgm, Vread, Vverify, Vpass, Vdsl, Vssl, Vsl, and Vpg based on the program loop, the erase loop, and the read operation on the memory cells based on the voltage control signal CMDv of the control circuit 120. Here, the operating voltages Verase, Vpgm, Vread, Vverify, Vpass, Vdsl, Vssl, Vsl, and Vpg may include an erase voltage Verase, a program voltage Vpgm, a read voltage Vread, a pass voltage Vpass, select voltages Vdsl and Vssl, a common source voltage Vsl, a pipe gate voltage Vpg, and/or the like. The voltage supply circuit 130 outputs the operating voltages Verase, Vpgm, Vread, Vverify, Vpass, Vdsl, Vssl, Vsl, and Vpg to the local lines SSL, WL0 to WLn, PG, and DSL of the selected memory block and the common source line SL in response to the row address signal RADD of the control circuit 120.

The read/write circuit 140 may include a plurality of page buffers PB respectively connected to the memory array 110 through the bit lines BL. The page buffers PB may be connected to the bit lines BL, respectively. For example, one page buffer PB may be connected to one bit line. During the program operation, the page buffers PB selectively precharge the bit lines BL based on the operation control signal CMDpb of the control circuit 120 and data DATA to be stored in the memory cells. During the program verification operation or the read operation, based on the operation control signal CMDpb of the control circuit 120, the voltage variations or the current flows of the bit lines BL are sensed after the bit lines BL are precharged, and then, the data read from the memory cell may be latched.

The control circuit 120 may include a ROM 121 configured to store algorithm related to operations on the memory block (for example, a program operation, an erase operation, a read operation, and a verification operation. The control circuit 120 may include a storage part 122 configured to set data required to set operation conditions (for example, a voltage condition, a timing of voltage application, and/or the like) of the memory block. When the supply of a power voltage starts and a level of the power voltage increases to a stable level, the operation circuits 120 to 140 read data of the operation condition from the cam block 110CB, and store the read data in the storage part 122. Then, the operation circuits 120 to 140 may perform a program loop, an erase loop, and a read operation based on the algorithm stored in the ROM 121 and the operation conditions stored in the storage part 122.

The page buffers PB included in the read/write circuit 140 may include at least one or more latch circuits LAT1, LAT2, and LAT3. Each of the latch circuits LAT1, LAT2, and LAT3 may be used for different uses. For example, a first latch circuit LAT1 may be used as a cache latch, and second and third latch circuits LAT2, LAT3 may be used to latch input data or latch the read data. For example, in a test mode, the latch circuit (for example, LAT1) may be used to latch the algorithm input from the outside or the algorithm read from the preliminary block 110EB, and the second and third latch circuits LAT2 and LAT3 may be used to latch the input data or latch the read data.

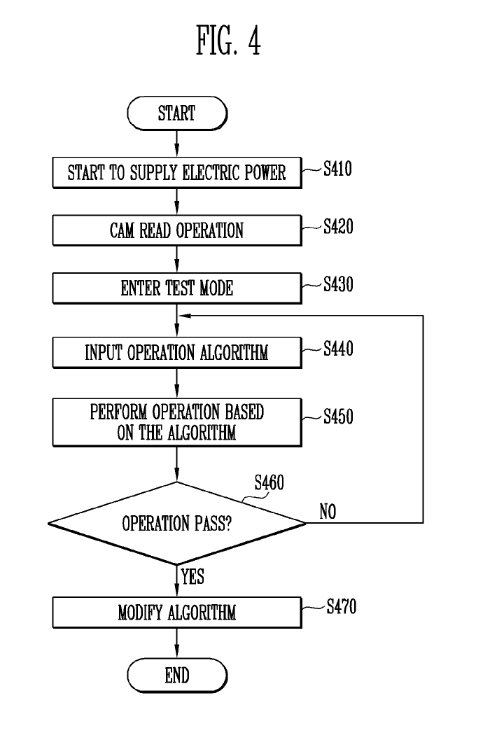

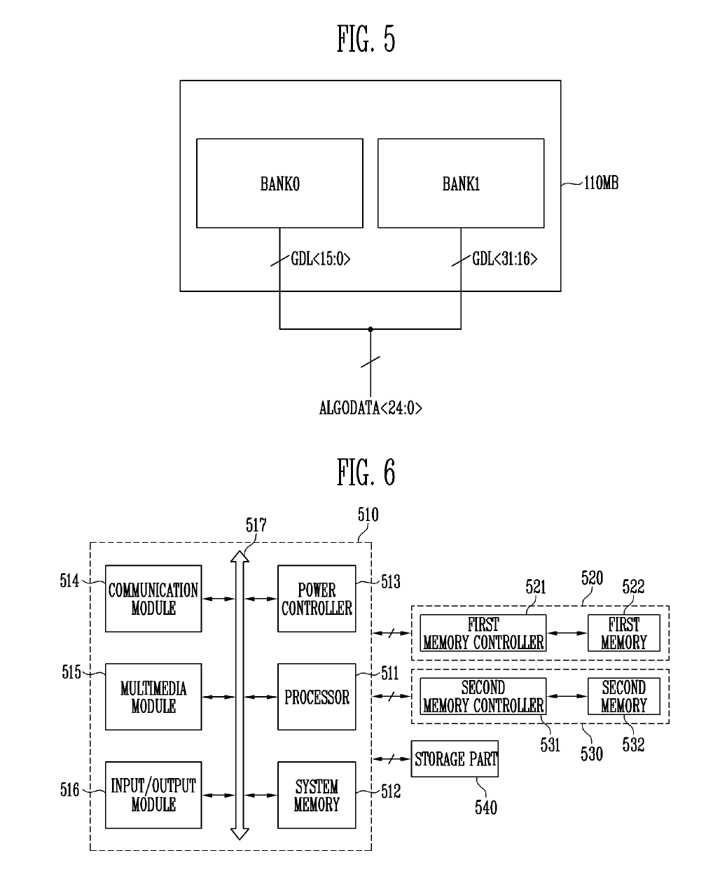

Hereinafter, a method of operating the semiconductor device including the above structures will be described. FIG. 4 is a flow chart illustrating a representation of an example of a method of operating a semiconductor device according to the various embodiments. FIG. 5 is a view illustrating a representation of an example of a method of operating a semiconductor device according to the various embodiments.

Referring to FIGS. 1 and 4, in S410, the supply of a power voltage starts (i.e., start to supply electric power).

In S420 (i.e., cam read operation), when the power voltage increases to a stable level, the operation circuits 120 to 140 read data required to set operation conditions from a cam block 110CB, and store the read data in a storage part 122. The operation in S320 may be referred to as a cam read operation. The cam read operation is performed when the supply of the power voltage starts regardless of a normal mode or a test mode.

The data of the operation conditions may be input from the outside, but may be changed by the operation circuits 120 to 140 when various operations are performed, and the changed data may be stored again in the cam block 110CB by the operation circuits 120 to 140. The data of the operation conditions stored in the cam block 110CB may be continuously updated by the operation circuits 120 to 140.

The algorithm stored in the ROM 121 maintains and is not changed although the power supply is cut off. In the normal mode, the operation circuits 120 to 140 perform predetermined operations based on the algorithm stored in the ROM 121 and the data to set the operation conditions stored in the storage part 122 when a command CMD from the outside is input.

When a problem is generated while the operation circuits 120 to 140 perform the operations based on the predetermined algorithm and conditions, change of the algorithm is required. In this example, in order to set an optimum algorithm, operations are performed by applying various algorithms. The algorithm stored in the ROM 121 may not be changed, but the algorithm is required to be input from the outside, and thus, a test mode for the above is required.

In S430 (i.e., enter test mode), the operation circuits 120 to 140 enter the test mode in response to a command signal CMD. In S440 (i.e., input operation algorithm), an operation algorithm is input from the outside. The algorithm input from the outside may be an algorithm for a test. A latch circuit (for example, LAT1) of the operation circuits 120 to 140 may latch the algorithm input from the outside. The operation circuits 120 to 140 may store the algorithm input from the outside in the preliminary block 110EB, and the algorithm read from the preliminary block 110EB may be latched to the latch circuit (for example, LAT1). The test algorithm may use only one word line (for example, a word line disposed in a middle) to be stored in the preliminary block 110EB, and may be securely stored in the memory cells of a selected word line through a single level cell (SLC) method.

Referring to FIG. 5, when the memory block 110MB includes a plurality of banks BANK0 and BANK1 (for convenience, only two banks are illustrated) and a capacity of the test algorithm ALGODATA<24:0> is greater than a page capacitor of the bank (for example, BANK0), the test algorithm ALGODATA<24:0> may be stored in a plurality of the banks BANK0 and BANK1 through data lines GDL<15:0> and GDL<31:16>.

In S450 (i.e., perform operation based on the algorithm), the operation circuits 120 to 140 perform a predetermined operation (for example, a test program operation or a test read operation) of the memory block 110MB based on the operation condition set by an external algorithm latched to the latch circuit LAT1 and the data stored in the storage part 122. When the test program operation is performed, in S440, test data to be stored in the memory block 110MB may be additionally input from the outside.

In S460 (i.e., operation pass?), the performed operation is determined whether the operation performed based on the external algorithm is suitable. After the operation circuits 120 to 140 determine the suitability of the operation, the operation circuits 120 to 140 may output the determined result to the outside. When the operation circuits 120 to 140 output only the result of the performed operation, the suitability of the operation may be determined based on the output result.

When the operation is determined to have a problem (i.e., No), another algorithm may be input from the outside in S440. Operations S450 and S460 may be performed based on the another algorithm received from the outside.

When the operation is determined to solve the problem in S460 (i.e., Yes), the algorithm may be modified in S470 (i.e., modify algorithm). For example, a new ROM 121 in which the modified algorithm is stored may be applied to the control circuit 120.

When the algorithm is modified by the above method, operation characteristics may be easily improved.

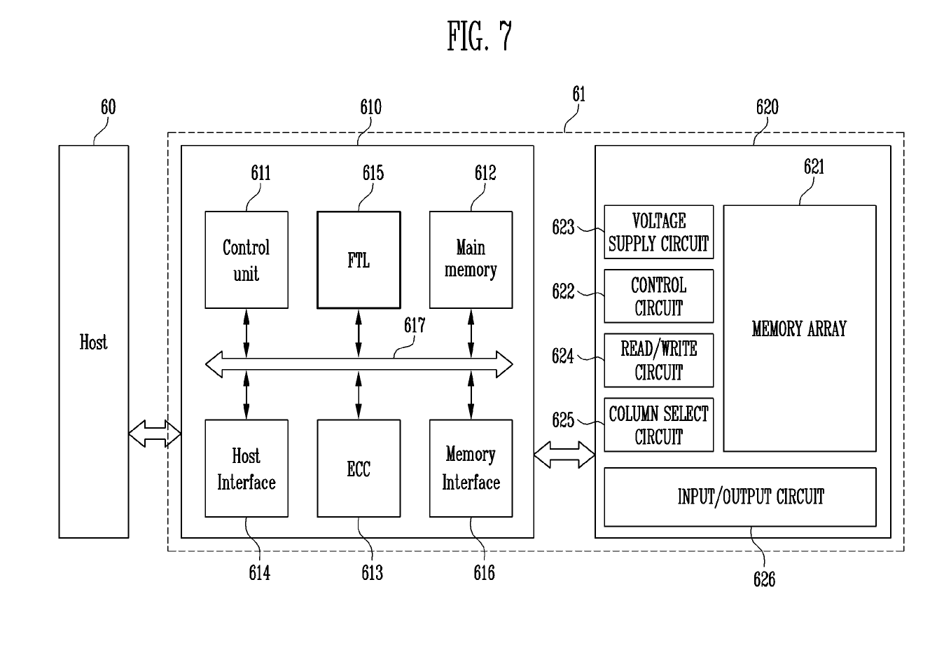

FIG. 6 is a block diagram illustrating a representation of an example of a structure of an electronic device according to the various embodiments.

The electronic device may include a computing device or a system capable of performing computer-readable commands. Examples of the electronic devices may include workstations, laptops, client-side terminals, servers, distributed computing systems, handheld devices, video game consoles, and/or the like.

Referring to FIG. 6, the electronic device may include a host 510, a first semiconductor device 520, and a second semiconductor device 530. The host 510 may include modules capable of performing various functions such as a processor 511, a system memory 512, a power controller 513, a communication module 514, a multimedia module 515, an input/output module 516, and/or the like, and a system bus 517 capable of mutually connecting between the above modules.

The processor 511 performs an operation system in the electronic device, and performs various calculation operations, and controls the system memory 512, the power controller 513, the communication module 514, the multimedia module 515, the input/output module 516, which are included in the host 510, the first semiconductor device 520, the second semiconductor device 530, and a storage part 540. The processor 511 may include a central processing unit (CPU), a graphic processing unit (GPU), a multi-media processor (MMP), and a digital signal processor. Also, a combination of processor chips having various functions such as an application processor (AP) may be embodied as a system on chip shape.

The system memory 512 stores information about an operation system, and stores data processed by the processor 511, and stores data generated from the operation result of the processor 511.

The power controller 513 may control an amount of a power supply so that a suitable electric power is supplied to operate and function the processor 511 and each component included in the electronic device. The above power controller 513 may include a power management IC (PMIC), and/or the like. The power controller 513 may receive a power source from the outside of the electronic device, or receive a power source from a battery inside the electronic device.

The communication module 514 may perform transcieving a signal between the processor 511 and a device outside the electronic device based on various communication protocols. The communication module 514 may include a module capable of being connected to a wired network, a module capable of being connected to a wireless network, and/or the like. The wired network may perform the signal transcieving in a communication method such as a local area network (LAN), an ethernet, a power line communication (PLC), and/or the like. The wireless network may perform the signal transcieving operation in a communication method such as a bluetooth, and a radio frequency identification (RFIC), a long term evolution (LTE), a wireless broadband internet (Wibro), a wideband CDMA (WCDMA), and/or the like.

The multimedia module 515 may perform calculation or input/out of multimedia data based on the control of the processor 511. The multimedia module 515 may be connected to a camera device, an audio device, a 2D or 3D graphic device, a display device, an A/V output device, and/or the like, and input or output the multimedia data.

The input/output module 516 may receive a signal through a user interface, and also output a specific signal to the user. The input/output module 516 may output signals through a keyboard, a keypad, a mouse, a stylus, and a microphone, and/or the like. The input/output module 516 may output signals through a touch screen device in a constant pressure type, a touch screen device in an electrostatic type, and/or the like., and receive the signal, and output the signal through a speaker, an earphone, a printer, a display device, and/or the like.

The first semiconductor device 520 may store the data received from the host 510 based on control of the processor 511 included in the host 510, and output the stored data to the host 510. The first semiconductor device 520 may include at least one or more first memory controllers 521 and first memories 522.

In order to control data input/output operation on the first memory 522, the first memory controller 521 may transmit information or signals, such as a clock, a command/address, a data strobe signal, data, and/or the like, to the first memory 522 based on control of the processor 511 included in the host 510. The above information or signals may be transmitted through the same channel or a different channel.

The first memory 522 may input/output data in response to the clock, the command/address, the data strobe signal, and/or the like applied from the first memory controller 521. The above first memory 522 may be embodied by volatile memory devices such as a static RAM (SRAM), a dynamic RAM (DRAM), a synchronous DRAM, and/or the like.

The second semiconductor device 530 rapidly identifies the control signal received from the host 510, and operates or functions as a memory system capable of starting operations corresponding to the received control signal. The second semiconductor device 530 may include at least one or more second memory controllers 531 and second memories 532.

The second memory controller 531 may be connected to the second memory 532 through at least one or more channels. The second memory controller 531 may control read, program and erase operations of the second memory 532 based on the control of the processor 511.

The second memory 532 may be connected to the second memory controller 531 through a plurality of channels. The second memory 532 may include at least one or more nonvolatile memory devices such as a read only memory (ROM), a programmable ROM (PROM), an electrically erase and programmable ROM (EEPROM), and an electrically erasable and programmable ROM (EPROM), and/or the like. The second memory 532 may include at least one or more nonvolatile memory devices such as a flash memory, a phase change RAM (PRAM), a magnetic RAM (MRAM), resistive RAM (RRAM), a ferroelectric RAM (FRAM), and/or the like. One or more nonvolatile memory devices may be connected to one channel. The nonvolatile memory devices connected to one channel may be connected to the same control signal bus or data bus. The second memory 532 may be embodied by the semiconductor devices illustrated in FIGS. 1 to 4.

The electronic device may include the storage part 540 to store a large amount of data, or use a storage part outside the electronic device. The storage part 540 may be a mass information storage device to store data and commands for various structures of the electronic device. The storage part 540 may be embodied to a device such as one or more HDD, a flash based SSD, and/or the like.

The structures illustrated in FIG. 6 are classified into functions, and not physically classified. For example, two or more structures of FIG. 6 may be formed in one physical semiconductor chip or included in a single package.

FIG. 7 is a view illustrating a representation of an example of a structure of a semiconductor device including the memory according to the various embodiments.

Referring to FIG. 7, the semiconductor device may include a memory controller 610 and a memory 620.

The memory 620 may include a memory array 621, a control circuit 622, a voltage supply circuit 623, a read/write circuit 624, a column select circuit 625, and an input/output circuit 626 described in FIG. 1. Relationship between memory blocks of the memory array 621 and a read/write operation is the same as described above.

The memory controller 610 may control the memory 620. The memory controller 610 may exchange data with a host 60 through a host interface 614, and exchange data with the memory 620 through a memory interface 616. The memory controller 610 may include a control unit 611, a main memory 612, an error correction code (ECC) unit 613, a host interface 614, a flash transition layer (FTL) 615, and a memory interface 616, which may be connected to each other through a bus 617. The memory controller 610 may access the memory 620 in response to a request from the host 60. The memory controller 610 may control operations (for example, a read operation, a write operation, an erase operation, and/or the like) of the memory 620, and operate a firmware configured to control the memory 620.

The control unit 611 may be configured to control overall operations of the memory controller 610. The control unit 611 may control operations of functional units inside the memory controller 610 based on a firmware or a software. The control unit 611 may control an operation of the memory 620 in response to the request of the host 60.

The main memory 612 may be configured to store firmware or software operated by the control of the control unit 611 or store data required to drive the firmware or the software. The main memory 612 may be used as a working memory of the control unit 611. The main memory 612 may store data requested as a write operation from the host 60, or store data read from the memory 620. The main memory 612 may be used as a data buffer memory (or a data cache memory). The memory controller 610 may rapidly response to the request of the host 60 by a data buffering operation (or a data cache operation) of the main memory 612. The main memory 612 may be configured to store parameters related to an operation condition of a memory. The parameter may be provided from the memory 620 to the memory controller 610, and when the supply of electric power starts, the parameter is provided from the memory 620 and the provided parameter may be stored in the main memory 612. The memory controller 610 may control operation (for example, the program operation, the read operation, and the erase operation) of the memory 620 based on a condition set by the parameter stored in the main memory 612. In an embodiment, the main memory 612 may be configured as a nonvolatile memory such as an SRAM, a DRAM, a synchronous DRAM (SDRAM), and/or the like. In an embodiment, the main memory 612 may be configured as a nonvolatile random access memory such as a ferroelectric RAM (FRMA), a magnetic RAM (MRAM), a phase change RAM (PCRAM), a resistive RAM (ReRAM), and/or the like. In FIG. 7, the main memory 612 is described to be included in the memory controller 610, but the main memory 612 may be configured in the outside of the memory controller 610.

The host interface 614 may be configured to mutually connect the host 60 to the memory controller 610. For example, the host interface 614 may be configured to communicate with the host 60 through at least one of various interface protocols such as a multi media card (MMC), a universal flash storage (UFS), a parallel advanced technology attachment (PATA), a serial advanced technology attachment (STAT), a small computer system interface (SCSI), a serial-attached SCSI (SAS), a peripheral component interconnection (PCI), a PCI-Express (PCI-E), a secure digital (SD), a universal series bus (USB), etc.

The flash transition layer 615 may provide various control units based on characteristics of the memory 620. For example, the flash transition layer 615 may provide a unit configured to transform a logic address received from the host 60 to a physical address of a memory 61. The flash transition layer 615 may stablize and maintain information about a mapping relationship between the logic address and the physical address. The flash transition layer 615 may provide a unit configured to provide uniformity to the number of program operations and erase operations on memory blocks of the memory array 621. For example, the flash transition layer 615 may provide a wear leveling unit. The flash transition layer 615 may provide a unit configured to minimize the erased number of the memory block. For example, the flash transition layer 615 may provide a control unit such as merge, garbage collection, and/or the like.

The memory interface 616 may be configured to mutually connect the memory controller 610 to the memory 620. The memory interface 616 may be configured to provide control signals (for example, a command, an address, and/or the like) to the memory 620. Also, the memory interface 616 may communicate data with the memory 620.

The ECC unit 613 may perform an encoding operation adding parity data into data to be written in the memory 620, and a decoding operation detecting and correcting an error read from the memory 620 based on the parity data. The ECC unit 613 may correct the error of the data using an ECC algorithm such as a low density parity check (LDPC) code, a Bose-Chaudhuri Hocquenghem (BCH) code, a turbo code, a Reed-Solomon code, and/or the like. In FIG. 7, the ECC unit 613 is described to be configured in the memory controller 610, but the memory controller 610 may be configured outside thereof.

In an embodiment, the memory controller 610 and the memory 620 may be embodied into different chips. In an embodiment, the memory controller 610 and the memory 620 may be embodied into one semiconductor chip. For example, the memory controller 610 and the memory 620 may be included in a multimedia card (MMC, eMMC, RS-MMC, MMC-micro), a universal flash storage (UFS) device, a solid state driver (SSD), a secure digital card (SD, Mini-SD, Micro SD), a compact flash (CF) card, a smart media card, a USB storage device, a memory stick, and/or the like.

The memory unit may be embodied as any one among various package types. For example, the memory controller 610 and the memory 620 may be embodied as any one among a package on package (POP), a chip on board (COB), a system in package (SIP), a multi chip package (MCP), a wafer-level fabricated package (WFP), a wafer-level processed stack package (WSP), and/or the like.

According to the semiconductor device according to the various embodiments, operation characteristics may be easily improved.

Although the application is explained with reference to the various examples of embodiments, it will be apparent to those skilled in the art that various modifications can be made to the above-described embodiments without departing from the spirit or scope of the disclosure.

What is claimed is:

1. A semiconductor device comprising:
first to third memory blocks including memory cells; and
an operation circuit configured to perform an operation of the first to third memory blocks,
wherein the operation circuit is configured to receive an algorithm from outside the semiconductor device and store the algorithm in the second memory block, and perform an operation of the first memory block based on the stored algorithm.

2. The semiconductor device of claim 1, wherein the operation circuit is configured to perform an operation of the first memory block based on a first algorithm stored in the operation circuit while the operation circuit is operating in a normal mode.

3. The semiconductor device of claim 1, wherein the operation circuit comprises a ROM configured to store the first algorithm.

4. The semiconductor device of claim 1, wherein before the algorithm is input, the operation circuit enters a test mode.

5. The semiconductor device of claim 1, wherein after the algorithm stored in the second memory block is read, the operation circuit is configured to perform the operation of the first memory block based on the read algorithm.

6. The semiconductor device of claim 5, wherein the operation circuit comprises a latch circuit configured to latch the algorithm read from the second memory block.

7. The semiconductor device of claim 1, wherein the operation circuit is configured to perform a program operation or a read operation of the first memory block based on the algorithm.

8. The semiconductor device of claim 1, wherein the operation circuit is configured to store data to set a condition of a program operation or a read operation in the third memory block.

9. The semiconductor device of claim 8, wherein the operation circuit comprises a storage part configured to store the data.

10. The semiconductor device of claim 9, wherein when supply of electric power starts, the operation circuit is configured to read the data from the third memory block, and store the read data in the storage part.

11. The semiconductor device of claim 8, wherein the operation circuit is configured to perform the program operation or the read operation based on the condition set by the data.

12. The semiconductor device of claim 1, wherein the operation circuit is configured to store the algorithm only in memory cells of one word line selected from the second memory block in a single level cell (SLC) method.

13. A semiconductor device comprising:
memory blocks including memory cells; and
an operation circuit including a ROM configured to store a first algorithm and a latch circuit configured to latch a second algorithm input from outside the semiconductor device, and configured to perform an operation of the memory blocks based on one of the first algorithm and the second algorithm.

14. The semiconductor device of claim 13, wherein the operation circuit is configured to operate in a normal mode with the first algorithm and operate in a test mode with the second algorithm.

15. The semiconductor device of claim 13, wherein before the second algorithm is input from the outside, the operation circuit is configured to enter a test mode.

16. The semiconductor device of claim 13, wherein the operation circuit is configured to store data to set a condition of a program operation or a read operation in a cam block selected among the memory blocks.

17. The semiconductor device of claim 16, wherein the operation circuit comprises a storage part configured to store the data.

18. The semiconductor device of claim 17, wherein when supply of electric power starts, the operation circuit is configured to read the data from the cam block, and store the read data in the storage part.

19. The semiconductor device of claim 16, wherein the operation circuit is configured to perform the program operation or the read operation based on the condition set by the data.

20. The semiconductor device of claim 13, wherein the memory block comprises a plurality of banks, and when a capacity of the second algorithm is greater than a page capacity of the bank, the operation circuit is configured to divide and store the second algorithm in the banks.
